(19) United States
(12) Patent Application Publication
(10) Pub. No.: US 2026/0088120 A1
(43) Pub. Date: Mar. 26, 2026

(54) REPAIR SYSTEM FOR SYSTEM ON A CHIP

(71) Applicant: Cypress Semiconuctor Corporation, San Jose, CA (US)

(72) Inventor: Senwen KAN, Austin, TX (US)

(73) Assignee: Cypress Semiconuctor Corporation, San Jose, CA (US)

(21) Appl. No.: 18/898,404

(22) Filed: Sep. 26, 2024

(51) Int. Cl. G11C 29/44; G11C 29/12; G11C 29/42

(52) U.S. Cl. CPC G11C 29/4401; G11C 29/1201; G11C 29/42; G11C 29/44

(57) ABSTRACT

A system on a chip includes a plurality of tiles, a non-volatile memory, and a repair system. The repair system includes a cache and control logic. The control logic is configured to receive a repair data write request and a respective repair address and corresponding repair data for a respective tile of the plurality of tiles from a respective repair controller and store the corresponding repair data in the cache in a redundancy encoded and compressed format; write the contents of the cache to the non-volatile memory; and receive a repair data read request and the respective repair address for the respective tile from the respective repair controller, read the corresponding redundancy encoded and compressed repair data from the cache, decompress the repair data, decode the corresponding repair data with error detection and correction logic, and output the corresponding repair data to the respective repair controller.

### BACKGROUND

The number of physical tiles on a system on a chip is increasing. To achieve profitable yield targets, the tiles may need to be repaired. Typical solutions for managing repair data for a system on a chip are not scalable to tens or hundreds of tiles due to, for example, a lack of redundancy and/or a lack of fault tolerance.

For these and other reasons, a need exists for the present invention.

### SUMMARY

Some examples of the present disclosure relate to a system on a chip. The system on a chip may include a plurality of tiles. Each tile may include a repair controller. The system on a chip may include a non-volatile memory and a repair system communicatively coupled between the non-volatile memory and the repair controller of each respective tile of the plurality of tiles. The repair system may include a cache and control logic. The control logic may be configured to receive a repair data write request and a respective repair address and corresponding repair data for a respective tile of the plurality of tiles from a respective repair controller and store the corresponding repair data in the cache in a redundancy encoded and compressed format. The control logic may be configured to write the contents of the cache to the non-volatile memory. The control logic may be configured to receive a repair data read request and the respective repair address for the respective tile from the respective repair controller, read the corresponding redundancy encoded and compressed repair data from the cache, decompress the repair data, decode the corresponding repair data with error detection and correction logic, and output the corresponding repair data to the respective repair controller.

In some examples, the control logic may be further configured to populate the cache from the non-volatile memory in response to receiving the repair data read request and the cache not being populated. In some examples, the control logic may be further configured to generate check bits for the corresponding repair data using an error-detecting code and store the check bits in the cache with the corresponding repair data. In some examples, the check bits may include triple modular redundancy check bits and/or cyclic redundancy check bits.

In some examples, the control logic may be further configured to calculate a first hash of the respective repair address using a first hash function, calculate a second hash of the respective repair address using a second hash function different from the first hash function, and select a cache address at which to store and/or read the corresponding repair data based on the first hash and/or the second hash. In some examples, in response to the repair data write request, the control logic may be further configured to generate tag bits based on the respective repair address and store the tag bits in the cache with the corresponding repair data. In some examples, in response to the repair data read request, the control logic may be further configured to generate verification tag bits based on the respective repair address, read the corresponding repair data and tag bits from the cache based on the selected cache address, verify the generated verification tag bits match the tag bits read from the cache with the corresponding repair data, perform error detection and correction on the corresponding repair data, and output the corresponding repair data to the respective repair controller.

In some examples, in response to the repair data write request, the control logic may be further configured to generate a tablewalker index based on the selected cache address in response to the selected cache address being in a hash table segment of the cache and store the tablewalker index in the cache with the corresponding repair data. In some examples, in response to the repair data write request, the control logic may be further configured to generate a hashlink based on the selected cache address in response to the selected cache address being in an overflow segment of the cache, and store the hashlink in the cache with the corresponding repair data.

In some examples, the non-volatile memory may include a hash table segment and an overflow segment. In some examples, the cache may include a static random access memory (SRAM), a plurality of registers, or a plurality of latch arrays. In some examples, the non-volatile memory may include a one-time programmable memory.

Other examples of the present disclosure relate to a system on a chip. The system on a chip may include a plurality of tiles. Each tile may include a repair controller. The system on a chip may include a non-volatile memory and a repair system communicatively coupled between the non-volatile memory and the repair controller of each respective tile of the plurality of tiles. The repair system may include a cache to store corresponding repair data for the plurality of tiles and repair system control logic. The repair system control logic may be configured to write the contents of the cache to the non-volatile memory and load the contents of the non-volatile memory to the cache. The repair system control logic may be configured to access the cache for a repair data write operation in response to a repair data write request from a respective repair controller. The repair system control logic may be configured to access the cache for a repair data read operation in response to a repair data read request from a respective repair controller.

In some examples, the repair system control logic may include a repair controller arbiter to serialize repair data write requests and repair data read requests received from each repair controller, a protocol engine to process the serialized repair data write requests and repair data read requests, and a finite state machine to control the operations of the repair system.

In some examples, the cache may include a static random access memory (SRAM) and cache control logic. The cache control logic may be configured to generate a first hash and a second hash based on a respective repair address for corresponding repair data for the plurality of tiles, select an address of the SRAM based on the first hash and/or the second hash at which to store the corresponding repair data, generate check bits for the corresponding repair data, combine the corresponding repair data with the check bits, and write the corresponding repair data to the selected address in the SRAM.

In some examples, the cache control logic may be further configured to enable the SRAM to read the corresponding repair data from the selected address in the SRAM, detect errors and/or correct the corresponding repair data, and pass the corresponding repair data to the repair system control logic.

Yet other examples of the present disclosure relate to a method for self-repair of tiles of a system on a chip. The method may include executing a built-in self-test of each tile of a plurality of tiles of the system on a chip to generate corresponding repair data for each tile. The method may include receiving, at a repair system from each tile, a respective repair address and corresponding repair data. The method may include selecting a cache address based on the respective repair address at which to write the corresponding repair data to a cache. The method may include writing the contents of the cache to a non-volatile memory.

In some examples, selecting the cache address may include hashing the respective repair data address to generate a respective hash table write address and implementing a hash table lookup on the respective hash table write address in a hash table segment of the cache. In response to the hash table lookup on the respective hash table write address finding an empty slot in the hash table segment, the method may include writing the corresponding repair data to the empty slot. In response to the hash table lookup on the respective hash table write address finding an occupied slot in the hash table segment, the method may include hashing the respective repair data address to generate a corresponding hash table write offset and table walking the hash table segment based on the hash table write offset to find an empty slot in the hash table segment. In response to the table walking finding an empty slot in the hash table segment, the method may include writing the corresponding repair data to the empty slot. In response to the table walking not finding an empty slot in the hash table segment, the method may include writing the corresponding repair data to an overflow segment of the cache or in the non-volatile memory.

In some examples, the method may further include triggering a read of corresponding repair data to repair a respective tile. The method may further include in response to the cache not being populated, populating the cache from the non-volatile memory. The method may further include hashing the respective repair data address to generate a respective hash table read address and implementing a hash table lookup on the respective hash table read address in the hash table segment of the cache. In response to the hash table lookup on the respective hash table read address finding an empty slot in the hash table segment, the method may include returning a null to the respective tile. In response to the hash table lookup on the respective hash table read address finding an occupied slot in the hash table segment, the method may further include verifying the stored data at the hash table address corresponds to the respective repair address. In response to the verification of the stored data at the hash table address corresponds to the respective repair address, the method may include returning the corresponding repair data stored at the hash table read address. In response to not verifying the stored data at the hash table read address corresponds to the respective repair address, the method may further include hashing the respective repair data address to generate a corresponding hash table read offset and table walking the hash table segment based on the hash table read offset to find a next slot in the hash table segment. In response to the table walking finding the next slot empty, the method may include returning a null to the respective tile. In response to the table walking finding the next slot occupied, the method may further include verifying the stored data at the occupied slot corresponds to the respective repair address. In some examples, in response to the table walking exhausting the entire hash table segment with no occupied slot corresponding to the respective repair address, the method may further include reading the corresponding repair data from the overflow segment of the cache.

### BRIEF DESCRIPTION OF THE DRAWINGS

FIG. 1 is a block diagram illustrating an exemplary system on a chip including a repair system.

FIG. 2 is a block diagram illustrating an exemplary repair system for a system on a chip.

FIG. 3 is a block diagram illustrating an exemplary cache core for a repair system.

FIG. 4 is a block diagram illustrating an exemplary non-volatile memory for a repair system.

FIG. 5 is a block diagram illustrating an exemplary portion of a repair system.

FIG. 6 is a block diagram illustrating an exemplary data encoding scheme for encoding data in a repair system.

FIG. 7 is a block diagram illustrating an exemplary repair address space for a repair controller of a tile.

FIG. 8 is a functional block diagram illustrating an exemplary repair address and data translation process between a repair controller of a tile and a cache core of a repair system.

FIG. 9 is a functional block diagram illustrating an exemplary address and data translation process between multiple repair controllers and a cache core of a repair system.

FIG. 10 is a functional block diagram illustrating an exemplary write process including encoding data.

FIG. 11 is a functional block diagram illustrating an exemplary read process including decoding data.

FIG. 12 is a flow diagram illustrating an exemplary method for writing repair data to a repair system

FIG. 13 is a flow diagram illustrating an exemplary method for reading repair data from a repair system.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

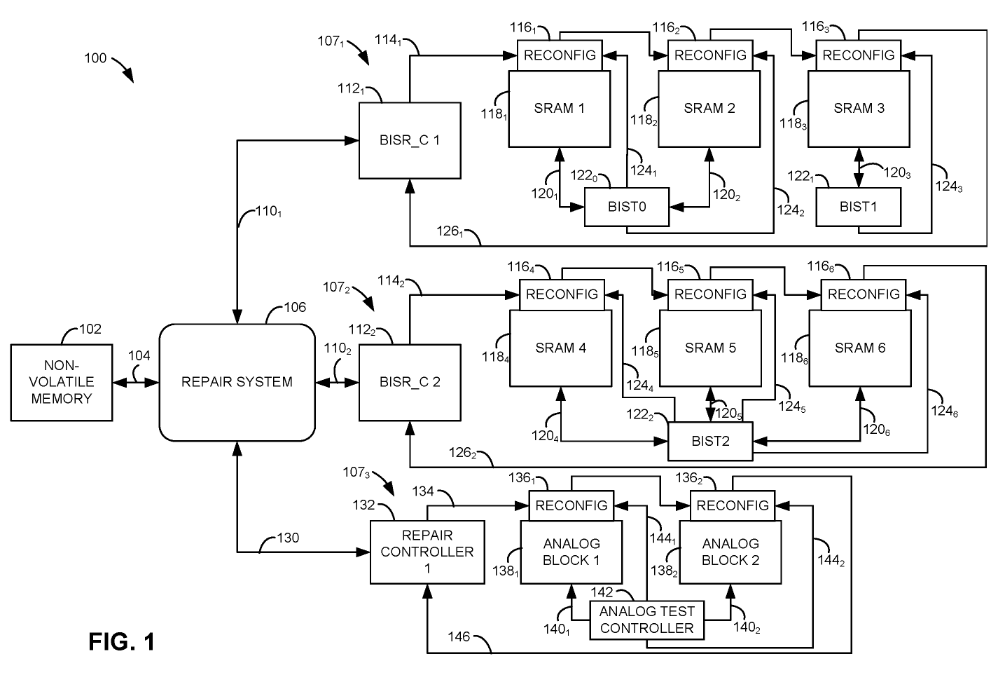

FIG. 1 is a block diagram illustrating an exemplary system on a chip 100. System on a chip 100 includes a non-volatile memory 102 (e.g., one-time programmable memory (OTP)), a repair system 106 and a plurality of tiles 107₁ to 107₃. While three tiles are illustrated in FIG. 1, system on a chip 100 may include any suitable number of tiles, such as 10, 50, 100, or more. The first tile 107₁ includes a first built in self-repair (BISR) controller (BISR_C 1) 112₁, reconfiguration blocks 116₁ to 116₃, static random access memories (SRAMs) 118₁ to 118₃, and built in self-test (BIST) circuits 122₀ and 122₁. Each reconfiguration block 116₁ to 116₃ corresponds to a SRAM 118₁ to 118₃, respectively. Repair system 106 is communicatively coupled to first BISR controller 112₁ through a communication path 110₁. BISR controller 112₁ is communicatively coupled to an input of each reconfiguration block 116₁ to 116₃ through a communication path 114₁ and to an output of each reconfiguration block 116₁ to 116₃ through a communication path 126₁. SRAM 118₁ and 118₂ are communicatively coupled to BIST circuit 122₀ through a communication path 120₁ and 120₂, respectively. BIST circuit 122₀ is communicatively coupled to reconfiguration blocks 116₁ and 116₂ through a communication path 124₁ and 124₂, respectively. SRAM 118₃ is communicatively coupled to BIST circuit 122₁ through a communication path 120₃. BIST circuit 122₁ is communicatively coupled to reconfiguration block 116₃ through a communication path 124₃.

The second tile 107₂ includes a second BISR controller (BISR_C 2) 112₂, reconfiguration blocks 116₄ to 116₆, SRAMs 118₄ to 118₆, and BIST circuit 122₂. Each reconfiguration block 116₄ to 116₆ corresponds to a SRAM 118₄ to 118₆, respectively. Repair system 106 is communicatively coupled to second BISR controller 112₂ through a communication path 110₂. BISR controller 112₂ is communicatively coupled to an input of each reconfiguration block 116₄ to 116₆ through a communication path 114₂ and to an output of each reconfiguration block 116₄ to 116₆ through a communication path 126₂. SRAM 118₄ to 118₆ are communicatively coupled to BIST circuit 122₂ through communication paths 120₄ to 120₆, respectively. BIST circuit 122₂ is communicatively coupled to reconfiguration blocks 116₄ to 116₆ through communication paths 124₄ to 124₆, respectively.

The third tile 107₃ includes a repair controller 132, reconfiguration blocks 136₁ and 136₂, analog blocks 138₁ and 138₂, and an analog test controller 142. Reconfiguration blocks 136₁ and 136₂ correspond to analog blocks 138₁ and 138₂, respectively. Repair system 106 is communicatively coupled to repair controller 132 through a communication path 130. Repair controller 132 is communicatively coupled to an input of each reconfiguration block 136₁ and 136₂ through a communication path 134 and to an output of each reconfiguration block 136₁ and 136₂ through a communication path 146. Analog blocks 138₁ and 138₂ are communicatively coupled to analog test controller 142 through communication paths 140₁ and 140₂, respectively. Analog test controller 142 is communicatively coupled to reconfiguration blocks 136₁ and 136₂ through communication paths 144₁ and 144₂, respectively. Each Analog block 138₁ and 138₂ may include an on chip current regulator, an analog to digital converter, or another analog circuit.

Each BISR controller 112₁and 112₂ controls the built in self-repair processes for the corresponding SRAMs 118₁ to 118₆ and operates in conjunction with corresponding BIST circuits 122₀ to 122₂ for testing and repairing the SRAMS. Accordingly, BIST circuit 122₀ is controlled by the tester, which is external to the chip and not shown in FIG. 1, to test and generate valid repair values for SRAMs 118₁ and 118₂. Subsequently, the BISR controller 112₁ sends the repair data for SRAMs 118₁ and 118₂ using the repair values from BIST circuit 122₀ to repair system 106 for permanent storage. BIST circuit 122₁ is controlled by the tester to test and generate valid repair values for SRAM 118₃. BISR controller 112₁ sends repair data for SRAM 118₃ to repair system 106 for permanent storage using repair values generated by BIST circuit 122₁. BIST circuit 122₂ is controlled by the tester to test and generate valid repair values for SRAMs 118₄, 118₅, and 118₆. BISR controller 112₂ sends repair data for SRAMs 118₄, 118₅, and 118₆ to repair system 106 for permanent storage using the repair values from BIST circuit 122₂. The repair data stored by the repair system 106 can then be retrieved at a later time during the device’s lifecyle by BISR controller 112₁and 112₂ and populated into the reconfiguration blocks 116₁ to 116₆ to repair the corresponding SRAMs 118₁ to 118₆.

Repair controller 132 controls the built in self-repair process for the analog blocks 138₁ and 138₂ and works with the analog test controller 142 for testing and repairing the analog blocks. Accordingly, analog test controller 142 is controlled by the tester tests and generates repair data for analog blocks 138₁ and 138₂. The repair controller can then send the repair data to the repair system 106 for permanent storage and later on retrieve this data and populate them into the reconfiguration blocks 136₁ and 136₂ to repair the corresponding analog blocks 138₁ and 138₂.

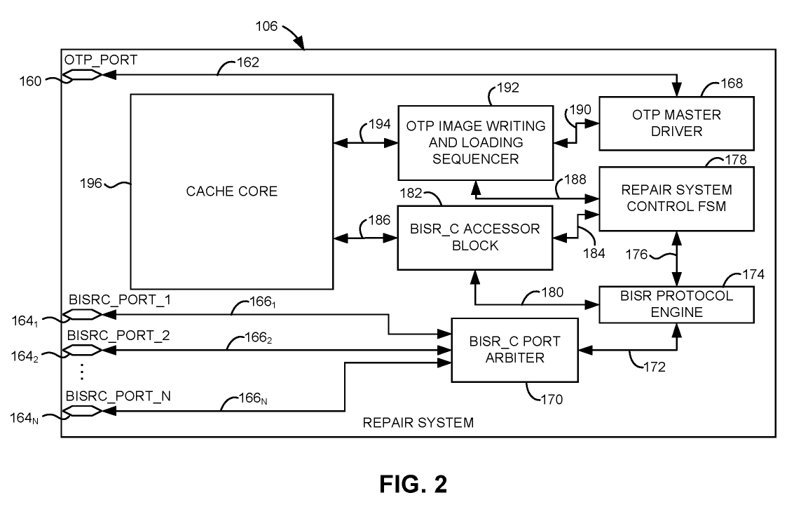

The repair data generated by each tile 107₁ to 107₃ is also transmitted (as a write request) to repair system 106 via each respective BISR controller 112₁ and 112₂and repair controller 132. Repair system 106, as further described below with reference to FIGS. 2-13, encodes and compresses the repair data and stores the encoded and compressed repair data in the non-volatile memory 102. In response to a read request, repair system 106 loads the requested repair data (e.g., from non-volatile memory 102 or a cached version of the data), decompresses and decodes the repair data, and transmits the decompressed and decoded repair data to the requesting BISR controller 112₁ or 112₂or repair controller 132. The requested repair data may be used to repair the respective tile via the corresponding reconfiguration blocks 116₁ to 116₆ or 136₁ and 136₂ (e.g., after a power cycle, after a reset, etc.).

In some examples, non-volatile memory (NVM) 102 may be a one-time programmable memory (OTP), such as an efuse programmable read-only memory, an antifuse programmable read-only memory, or a type of non-volatile random access memory with OTP emulation (e.g., OTP behavior can be emulated provided there is very little ability of changing the programmed state once a cell or bit is set). In the following description, while OTP may be used to refer to the NVM 102, it is noted that the NVM 102 is not necessarily one-time programmable and any reference to OTP may also apply to other types of NVM.

FIG. 2 is a block diagram illustrating an exemplary repair system 106. In some examples, repair system 106 provides the repair system for system on a chip 100 of FIG. 1. Repair system 106 may include an OTP port 160 and a plurality of BISR controller ports (BISRC_PORT_1 to BISRC_PORT_N) 164₁ to 164_{N}, where “N” is any suitable number of ports to support each tile on the system on a chip that utilizes repair data. Repair system 106 may further include a cache (e.g., cache core) 196 and control logic 168, 170, 174, 178, 182, and 192. The control logic may include an OTP master driver 168, a BISR controller port arbiter 170, a BISR protocol engine 174, a repair system control finite state machine (FSM) 178, a BISR controller accessor block 182, and an OTP image writing and loading sequencer 192.

The OTP port 160 is communicatively coupled to the OTP master driver 168 through a communication path 162. Each BISR controller port 164₁ to 164_{N} is communicatively coupled to the BISR controller port arbiter 170 through a communication path 166₁ to 166_{N}, respectively. The BISR controller arbiter 170 is communicatively coupled to the BISR protocol engine 174 through a communication path 172. The BISR protocol engine 174 is communicatively coupled to the BISR controller accessor block 182 through a communication path 180 and to the repair system control FSM 178 through a communication path 176. The repair system control FSM 178 is communicatively coupled to the BISR controller accessor block 182 through a communication path 184 and to the OTP image writing and loading sequencer 192 through a communication path 188. The BISR controller accessor block 182 is communicatively coupled to the cache core 196 through a communication path 186. The OTP master driver 168 is communicatively coupled to the OTP image writing and loading sequencer 192 through a communication path 190. The OTP image writing and loading sequencer 192 is communicatively coupled to the cache core 196 through a communication path 194.

The OTP port 160 is a bidirectional interface that may be communicatively coupled to a non-volatile memory (e.g., 102 of FIG. 1). Each BISR controller port 164₁ to 164_{N} is a bidirectional interface that may be communicatively coupled to a respective repair controller (e.g., a BISR controller 112₁ or 112₂ ora repair controller 132 of FIG. 1 or another repair controller of the system on a chip 100). Each BISR controller port 164₁ to 164_{N} may receive handshake signals to indicate either a write or a read request from a respective repair controller. The repair system 106 may indicate the status of a current request to the respective repair controller, such as whether a given request is in process or completed. Each BISR controller port 164₁ to 164_{N} may receive signals from a respective repair controller including repair data to write to the repair system 106. Each BISR controller port 164₁ to 164_{N} may also transmit signals to a respective repair controller including read repair data requested by the respective repair controller from the repair system 106.

The BISR controller port arbiter 170 serves multiple repair controllers (via BISR controller ports 164₁ to 164_{N}) such that more than one request may occur simultaneously. Therefore, BISR controller port arbiter 170 may serialize the requests from the repair controllers based on an arbitration scheme. In some examples, the BISR controller port arbiter 170 may use a round robin arbitration scheme to service requests from the repair controllers in a circular manner. For example, BISR controller port arbiter 170 may check to see if there is a request on a first BISR controller port. If there is a request on the first BISR controller port, the request is serviced first. If there is no request on the first BISR controller port, the BISR controller port arbiter 170 moves to a second BISR controller port, and so on, regardless of when each request is received and services the request if there is one. In some examples, the BISR controller port arbiter 170 may use a priority based arbitration scheme. For example, if a third BISR controller port has priority over a first BISR controller port or a second BISR controller port, when requests are received on the first BISR controller port and the third BISR controller port concurrently, then the request on the third BISR controller port is served first. In some examples, the BISR controller port arbiter 170 may use a time of arrival arbitration scheme including logic to determine which BISR controller port generated the earliest request and proceed to service the earliest unserved request followed by other unserved requests in the order they are received.

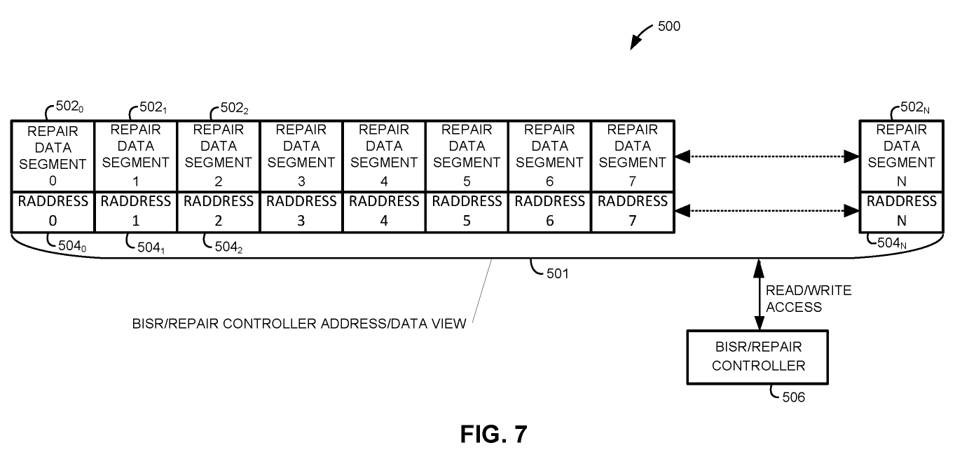

The BISR protocol engine 174 interprets requests once they are arbitrated by the BISR controller port arbiter 170. When the repair system control FSM 178 is ready to service the next request, the repair system control FSM 178 will signal to the BISR protocol engine 174 to start processing a pending request. The BISR protocol engine 174, which may contain its own FSM, may interpret the input request (one request at a time) and translate the request into actions and sequences that the repair system control FSM 178 can act upon or can sit in idle. The requests may include, for example, read requests, write requests, invalid requests, idle operation, BISR port active/not active). As the BISR protocol engine 174 completes processing the current request, the BISR protocol engine 174 may send an address (e.g., RAddress from a BISR/repair controller as further described below with reference to FIG. 7) to the BISR controller accessor block 182 along with the read or write signaling and the corresponding write data, if any. The repair system control FSM 178 may stall the BISR protocol engine 174 to hold steady the current request signaling to the BISR controller accessor block 182 until the repair system control FSM 178 completes servicing the current request, at which point the repair system control FSM 178 may tell the BIST protocol engine 174 that the current request is processed and a complete status may be signaled to the respective BISR controller port 164₁ to 164_{N}. If a read request is served, then the read data may be made available by the BISR protocol engine 174 back to the respective BISR controller port 164₁ to 164_{N}.

The repair system control FSM 178 is the main control FSM for the repair system 106 and enables the operation of all other blocks of repair system 106. In a reset state. the repair system control FSM 178 does not allow any request to be served. When in an idle/ready state, the repair system control FSM 178 enables all the other blocks of repair system 106 and puts them into an idle/ready state as well. In some examples, when in the idle state, the repair system control FSM 178 may put all the other blocks of repair system 106 into a clock gated and/or lower power state. In the idle state, the repair system control FSM 178 waits for an event generated from the BISR protocol engine 174. In response to a read or write request, if the cache core 196 is not populated with the data stored in the non-volatile memory (e.g., OTP) 102 of FIG. 1, the repair system control FSM 178 requests the OTP image writing and loading sequencer 192 to load any stored OTP contents into the cache core 196. The OTP master driver 168 reads data from the OTP or writes data to the OTP in response to requests from OTP image writing and loading sequencer 192. If the cache core 196 is populated, then the repair system control FSM 178 will proceed to process the request. In response to either a read or write request, the repair system control FSM 178 may enable the BISR controller accessor block 182 to generate either a read or write transaction for the cache core 196. Once the BISR protocol engine 174 signals back that none of the BISR controller ports 164₁ to 164_{N} are active, and if there is new data in the cache core 196, the repair system control FSM 178 may trigger the OTP image writing and loading sequencer 192 to write the data cached in the cache core 196 back into the OTP. Once no pending transactions are detected, the repair system control FSM 178 may put the repair system 106 back into the idle state.

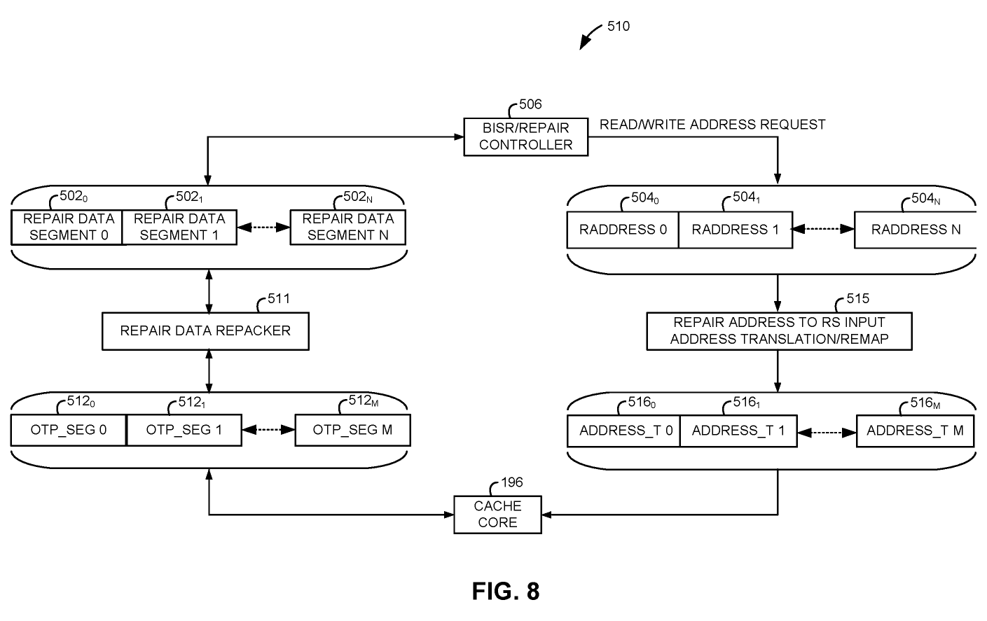

The BISR controller accessor block 182 converts the request packet from the BISR protocol engine 174 {Write/Read, RAddress, Data} into a packet {Write/Read, Address_T, repacked Data} for the cache core 196 as further described below with reference to FIG. 8. The BISR controller accessor block 182 also converts the response packet from the cache core 196 into a data format that can be interpreted by the BISR/repair controller. The BISR controller accessor block 182 is enabled by the repair system control FSM 178.

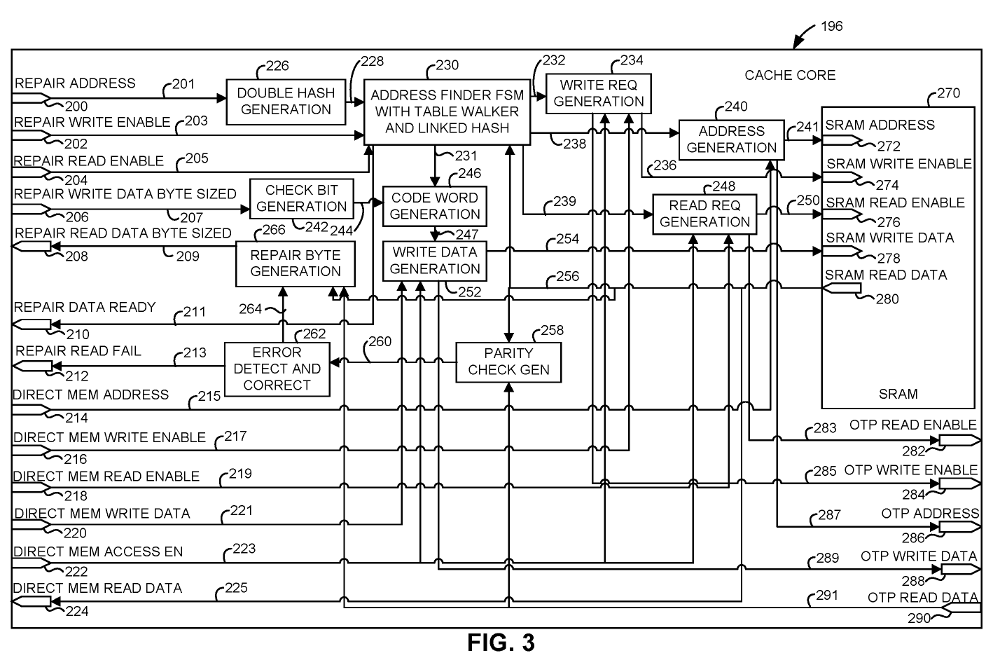

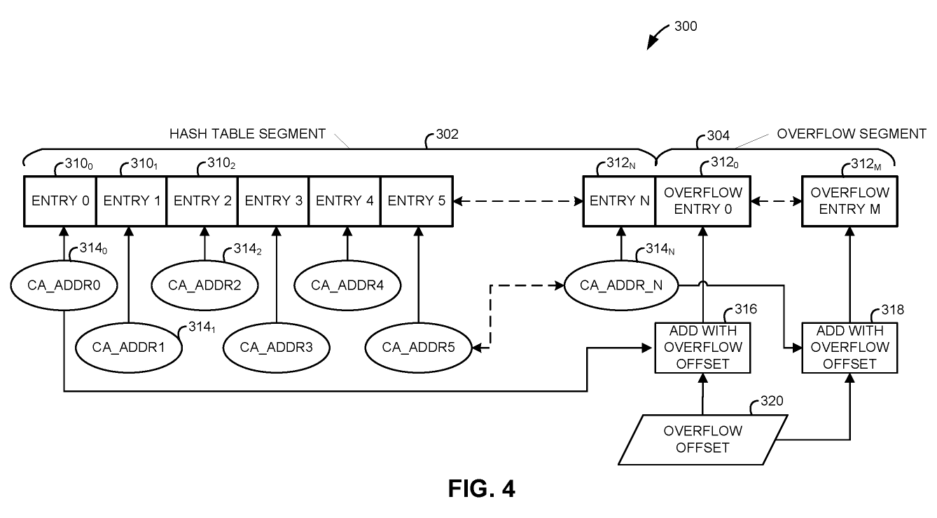

The cache core 196 performs encoding on the data written to the cache core. The cache core 196 may directly issue write requests to the OTP image writing and loading sequencer 192 when the cache core 196 determines that an overflow segment is to be written as will be described below with reference to FIG. 4. The cache core 196 may also generate the direct read access of the overflow region if needed during a tablewalk, which is described below with reference to FIGS. 3-6. The cache core 196 also communicates to the repair system control FSM 178 on the access status (e.g., in progress, complete, failed) of the cache core 196.

FIG. 3 is a block diagram illustrating an exemplary cache core 196. In some examples, cache core 196 provides the cache core for the repair system 106 of FIG. 2. Cache core 196 may include a repair address interface 200 of FIG. 3., a repair write enable interface 202, a repair read enable interface 204, a repair write data byte sized interface 206, a repair read data byte sized interface 208, a repair data ready interface 210, a repair read fail interface 212, a direct memory address interface 214, a direct memory write enable interface 216, a direct memory read enable interface 218, a direct memory write data interface 220, a direct memory access enable interface 222, and a direct memory read data interface 224. Cache core 196 further includes control logic including a double hash generation block 226, an address finder FSM with table walker and linked hash block 230, a write request generation block 234, an address generation block 240, a check bit generation block 242, a code word generation block 246, a read request generation block 248, a repair byte generation block 266, a write data generation block 252, an error detection and correction block 262, and a parity check generation block 258. Cache core 196 further includes a static random access memory (SRAM) 270. SRAM 270 may include a SRAM address interface 272, a SRAM write enable interface 274, a SRAM read enable interface 276, a SRAM write data interface 278, and a SRAM read data interface 280. Cache core 196 further includes an OTP read enable interface 282, an OTP write enable interface 284, an OTP address interface 286, an OTP write data interface 288, and an OTP read data interface 290.

The repair address interface 200 is communicatively coupled to the input of the double hash generation block 226 through a communication path 201. The output of the double hash generation block 226 is communicatively coupled to a first input of the address finder FSM with table walker and linked hash block 230 through a communication path 228. The repair write enable interface 202 is communicatively coupled to a second input of the address finder FSM with table walker and linked hash block 230 through a communication path 203. The repair read enable interface 204 is communicatively coupled to a third input of the address finder FSM with table walker and linked hash block 230 through a communication path 205. An output of the address finder FSM with table walker and linked hash block 230 is communicatively coupled to an input of the code word generation block 246 through a communication path 231, to an input of write request generation block 234 through a communication path 232, to address generation block 240 through a communication path 238, and to read request generation block 248 through a communication path 239.

The output of write request generation block 234 is communicatively coupled to the SRAM write enable interface 274 through a communication path 236. The output of address generation block 240 is communicatively coupled to the SRAM address interface 272 through a communication path 241. The output of read request generation block 248 is communicatively coupled to the SRAM read enable interface 276 through a communication path 250.

The repair write data byte sized interface 206 is communicatively coupled to the input of the check bit generation block 242 through a communication path 207. The output of check bit generation block 242 is communicatively coupled to an input of code word generation block 246 through a communication path 244. The output of the code word generation block 246 is communicatively coupled to an input of the write data generation block 252 through a communication path 247. The output of write data generation block 252 is communicatively coupled to the SRAM write data interface 278 through a communication path 254.

The repair read data byte sized interface 208 is communicatively coupled to the output of the repair byte generation block 266 through a communication path 209. An input of repair byte generation block 266 is communicatively coupled to an output of error detection and correction block 262 through a communication path 264. An input of repair byte generation block 266 is communicatively coupled to the SRAM read data interface 280 through a communication path 256.

The repair data ready interface 210 is communicatively coupled to an output of the address finder FSM with table walker and linked hash block 230 through a communication path 211. The repair read fail interface 212 is communicatively coupled to an output of the error detection and correction block 262 through a communication path 213. The direct memory address interface 214 is communicatively coupled to an input of address generation block 240 through a communication path 215. The direct memory write enable interface 216 is communicatively coupled to an input of the write request generation block 234 through a communication path 217. The direct memory read enable interface 218 is communicatively coupled to an input of read request generation block 248 through a communication path 219. The direct memory write data interface 220 is communicatively coupled to an input of the write data generation block 252 through a communication path 221. The direct memory access enable interface 222 is communicatively coupled to an input of the write data generation block 252, an input of the write request generation block 234, and an input of the read request generation block 248 through a communication path 223. The direct memory read data interface 224 is communicatively coupled to the SRAM read data interface 280 through a communication path 225. The SRAM read data interface 280 is also communicatively coupled to an input of the address finder FSM with table walker and linked hash block 230, an input of repair byte generation block 266, and the input of the parity check generation block 258 through a communication path 256. The output of the parity check generation block 258 is communicatively coupled to the input of error detection and correction block 262 through a communication path 260.

The OTP read enable interface 282 is communicatively coupled to an output of the read request generation block 248 through a communication path 283. The OTP write enable interface 284 is communicatively coupled to an output of the write request generation block 234 through a communication path 285. The OTP address interface 286 is communicatively coupled to an output of address generation block 240 through a communication path 287. The OTP write data interface 288 is communicatively coupled to an output of the write data generation block 252 through a communication path 289. The OTP read data interface 290 is communicatively coupled to an input of the repair byte generation block 266 and an input of the parity check generation block 258 through a communication path 291.

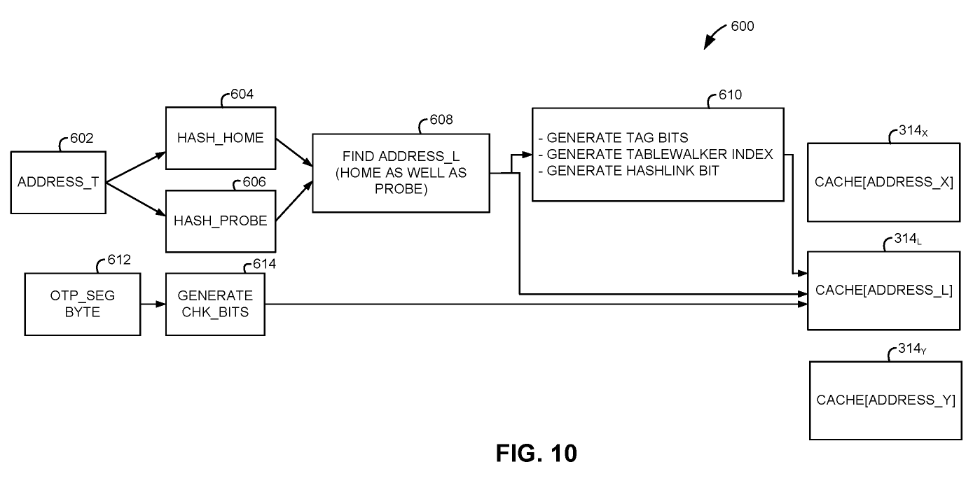

In response to a repair data write request, double hash generation block 226 receives a repair address (e.g., ADDRESS_T of FIGS. 8 and 10) from repair address interface 200, address finder FSM with table walker and linked hash block 230 receives a write enable from repair write enable interface 202, and check bit generation block 242 receives repair write data (e.g., OTP_SEG of FIGS. 8 and 10) from repair write data byte sized interface 206. Check bit generation block 242 generates check bits for the repair data, such as triple modular redundancy (TMR) check bits or cyclic redundancy code (CRC) check bits. Double hash generation block 226 may then calculate two hashes based on the repair address including a first hash (e.g., home hash) to generate a respective hash table write address and a second hash (e.g., probe hash) to generate a corresponding hash table write offset. The home hash and the probe hash are different hash functions. The home hash is used to generate a hash table address (e.g., cache address of SRAM 270) at which to store the repair data. The probe hash is used to generate a table walker index if the hash table address generated via the home hash is already occupied.

As will be further described below with reference to FIGS. 4-6, address finder FSM with table walker and linked hash block 230 finds an address to write the repair data to in the hash table (e.g., in the cache, such as SRAM 270) based on the two hashes from double hash generation block 226. Address finder FSM with table walker and linked hash block 230 first determines whether the hash table address generated via the home hash is occupied by reading, which is accomplished by setting the SRAM READ ENABLE 276 and the SRAM ADDRESS 272 to the home address value, the content of the cache at the home hash location. If the hash table address generated via the home hash is not occupied, the home hash location is selected to store the repair data. If the hash table address generated via the home hash is occupied, the hash table is table walked based on the probe hash until an open location in the hash table is found. If the table walking results in finding an open location, a table walker index is set equal to the multiple of the probe hash where the open location was found. If the table walking does not find an open location in the hash table, an available address in an overflow segment is selected and a hashlink bit is set indicating a link to the overflow segment.

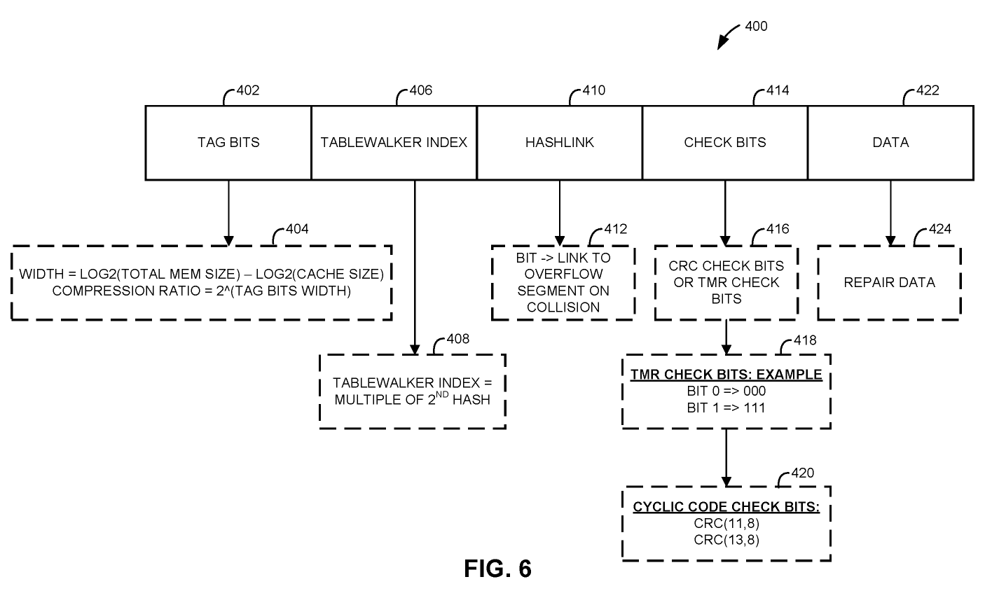

With an address found, write request generation block 234 generates a write enable signal to enable SRAM 270 for a write operation via the SRAM write enable interface 274. Address generation block 240 generates an SRAM address, which is applied to SRAM address interface 272, at which to write the repair data within SRAM 270 based on the found address. Code word generation block 246 generates a code word based on the check bits from check bit generation block 242, tag bits to be described below, the table walker index, the hashlink, and the repair data as will be further described below with reference to FIG. 6. Write data generation block 252 generates write data, which is applied to the SRAM write data interface 278, based on the generated code word to write the repair data to the SRAM 270.

In response to a repair data read request, double hash generation block 226 receives a repair address from repair address interface 200 and address finder FSM with table walker and linked hash block 230 receives a read enable from repair read enable interface 204. Double hash generation block 226 then calculates the two hashes based on the repair address including the home hash to generate a respective hash table read address and the probe hash to generate a corresponding hash table read offset as previously described. Address finder FSM with table walker and linked hash block 230 finds an address to read the repair data from based on the two hashes from double hash generation block 226. With the address found, read request generation block 248 generates a final read enable signal, which is applied to SRAM read enable interface 276, to enable SRAM 270 for a final read operation. Address generation block 240 generates an SRAM address, which is applied to SRAM address interface 272, to read the repair data from SRAM 170 based on the found address. The repair data is read out of SRAM 270 via SRAM read data interface 280 and passed to address finder FSM with table walker and linked hash block 230, to parity check generation block 258, and to repair byte generation block 266.

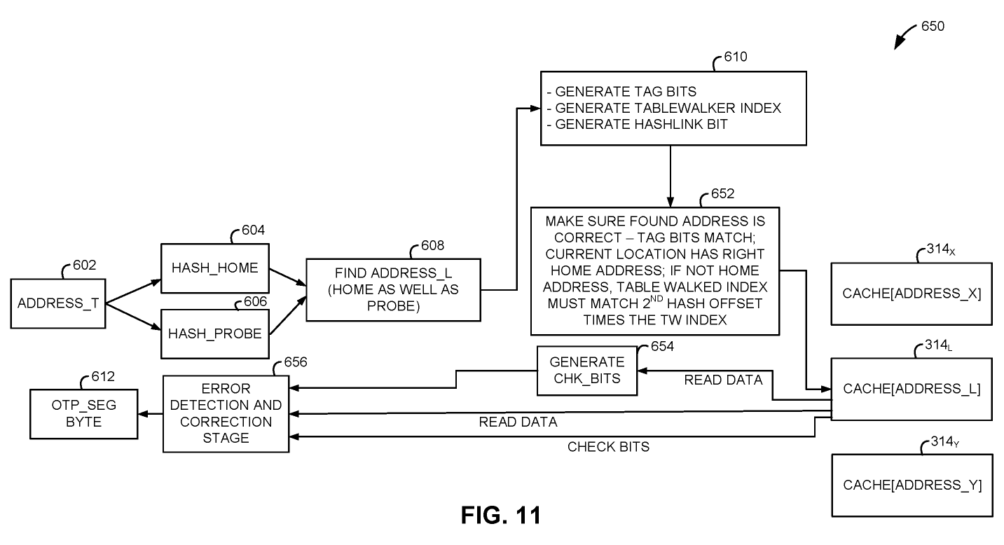

The address finder FSM with table walker and linked hash block 230 verifies the correct data has been read based on the tag bits as will be further described below with reference to FIG. 11. The parity check generation block 258 generates check bits based on the read repair data to compare to the check bits generated by check bit generator block 242 and stored with the repair data in SRAM 270. The error detection and correction block 262 then detects and corrects (if possible) any error in the read repair data. The repair byte generation block 266 prepares the repair data for output via repair read data byte sized interface 208. When the repair data is ready for output, address finder FSM with table walker and linked hash block 230 outputs a repair data ready signal via repair data ready interface 210. In response to the repair data read failing (e.g., data not found, data corrupted and uncorrectable, etc.), the error detection and correction block 262 outputs a repair read fail signal via repair read fail interface 212.

For a direct memory write request into the SRAM 270 or cache, the address generation block 240 receives a direct memory address via direct memory address interface 215, the write request generation block 234 receives an enable signal via the direct memory write enable interface 216 and an enable signal via the direct memory access enable interface 222, and the write data generation block 252 receives direct memory write data via the direct memory write data interface 220 and an enable signal via the direct memory access enable interface 222. The address generation block 240 then generates an SRAM address, which is applied to the SRAM address interface 272, at which to write the direct memory write data. The write request generation block 234 generates a write enable signal, which is applied to the SRAM write enable interface 274, to enable writing to the SRAM 270. The write data generation block 252 generates the write data based on the received direct memory write data, which is stored in the SRAM 270 via the SRAM write data interface 278.

For a direct memory read request, the address generation block 240 receives a direct memory address via the direct memory address interface 214 and the read request generation block 248 receives an enable signal via the direct memory read enable interface 218 and an enable signal via the direct memory access enable interface 222. The address generation block 240 then generates an SRAM address, which is applied to the SRAM address interface 272, from which to read the data. The read request generation block 248 generates a read enable signal, which is applied to the SRAM read enable interface 276, to enable reading from the SRAM 270. The requested data is then read from the SRAM 270 via the SRAM read data interface 280 and output on the direct memory read data interface 224.

In some examples, BISR controller accessor block 182 accesses cache core 196 for repair data read and write requests, while OTP image writing and loading sequencer 192 accesses cache core 196 for direct memory read and write requests. While cache core 196 includes SRAM 270, in other examples, another type of memory could be used in place of SRAM 270, such as a plurality of registers or a plurality of latch arrays.

FIG. 4 is a block diagram illustrating an exemplary non-volatile memory 300. In some examples, non-volatile memory 300 is used for non-volatile memory (e.g., OTP) 102 of FIG. 1. The non-volatile memory 300 includes a hash table segment 302 and an overflow segment 304. The hash table segment 302 includes entries 310₀ to 310_{N}, each corresponding to a cache address 314₀ to 314_{N}, respectively, where “N” is any suitable number of entries. The hash table segment 302 is written to the SRAM 270 of cache core 196 and then copied to the non-volatile memory 102 as previously described. Entries in the hash table segment 302 are written in response to a write request where an address (based on the home hash or probe hash previously described) is found for an open slot in the hash table. The overflow segment 304 includes overflow entries 312₀ to 312_{M}, where “M” is any suitable number of overflow entries. Overflow entry 312₀ may correspond to the cache address 314₀ plus an overflow offset 320 as indicated at 316, and overflow entry 312_{M} may correspond to cache address 314_{N} plus the overflow offset 320 as indicated at 318. Entries in the overflow segment are written in response to a write request where and an address (based on the home hash or probe hash previously described) is not found for an open slot in the hash table.

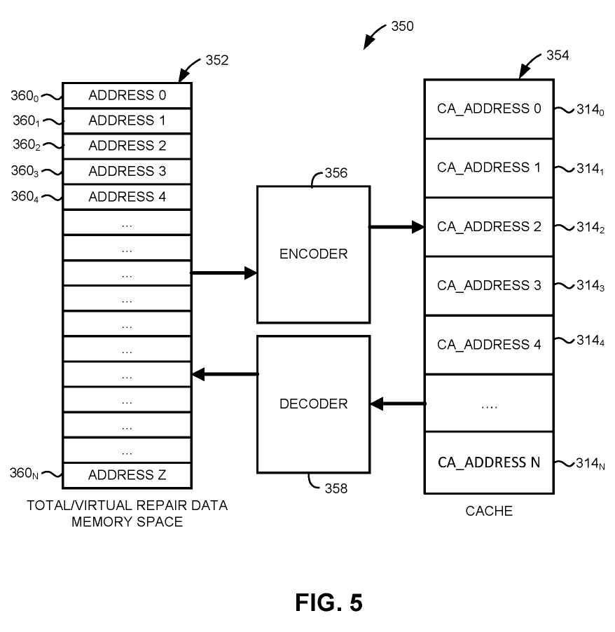

FIG. 5 is a block diagram illustrating an exemplary portion 350 of a repair system, such as repair system 106 of FIGS. 1 and 2. The repair system portion 350 includes a total/virtual repair data memory space 352 and a cache 354. The total/virtual repair data memory space 352 includes addresses 360₀ to 360_{Z}, which may correspond to an address space visible to a BISR/repair controller (e.g., 112₁, 112₂, and/or 132 of FIG. 1), where “Z” is any suitable number of addresses. The cache 354 includes cache addresses 314₀ to 314_{N} as previously described and illustrated with reference to FIG. 4, and may be provided by the SRAM 270 of cache core 196 of FIG. 3. The encoder 356 encodes the data from the total/virtual repair data memory space 352 to be written to the cache 354, such that corresponding repair data for a respective tile is stored in the cache 354 in a redundancy encoded and compressed format as will be further described below with reference to FIGS. 6 and 10. The decoder 358 decodes the data stored in the cache 354 to provide the original data back to the total/virtual repair data memory space 352, such that the corresponding redundancy encoded and compressed repair data from the cache is decompressed, decoded with error detection and correction logic, and output to the respective repair controller as will be further described below with reference to FIGS. 6 and 11. In some examples, the encoder 356 and the decoder 358 are incorporated into the BISR controller accessor block 182 and/or the cache core 196 of the repair system 106 of FIG. 2.

FIG. 6 is a block diagram illustrating an exemplary data encoding scheme 400 for the repair system. In some examples, the encoder 356 of FIG. 5 encodes the data according to the data encoding scheme 400. The encoding scheme 400 may include a tag bits field 402, a tablewalker index field 406, a hashlink field 410, a check bits field 414, and a data field 422. The tag bits field 402 may be generated based on the respective repair address received from a BISR/repair controller to provide a unique identifier for the data that may be used to verify the correct data has been read in response to a subsequent read request. The tag bits field may include a width equal to Log2(total memory size) minus Log2(cache size) and may include a compression ratio equal to 2^(tag bits width) as indicated at 404. The tag bits field may be generated by the code word generation block 246 of the cache core 196 of FIG. 3.

The tablewalker index field 406 may equal a multiple of the second (e.g., probe) hash as indicated at 408 to indicate the home address based on the first (e.g., home) hash was occupied and the hash table was table walked to find an open slot indicated by the tablewalker index. The tablewalker index may be set by the address finder FSM with table walker and linked hash block 230 of the cache core 196 of FIG. 3. In some examples, the tablewalker index field 406 may be excluded.

The hashlink field 410 may be a bit linked to the overflow segment in response to a collision (e.g., the home address based on the first (e.g., home) hash was occupied and the table walker did not find an empty slot in the hash table based on the second (e.g., probe) hash as indicated at 412. The hashlink field 410 may be set by the address finder FSM with table walker and linked hash block 230 of the cache core 196 of FIG. 3. In some examples, the hashlink field 410 may be excluded.

The check bits field 414 includes check bits generated for the data of the data field 422. The check bit field 414 may be set by the check bit generation block 242 of cache core 196 of FIG. 3. The check bits may be cyclic redundancy check (CRC) bits or triple modular redundancy (TMR) check bits as indicated at 416. An example of TMR check bits is indicated at 418 and includes a bit “0” encoded as “000” and a bit “1” encoded as “111”. An example of cyclic code check bits may be CRC(11,8) or CRC(13,8) as indicated at 420. The data 422 may include repair data as indicated at 424. A code word including the tag bits field 402, tablewalker index field 406, hashlink field 410, check bits field 414, and data field 422 may be generated by the code word generation block 246 of the cache core 196 of FIG. 3.

FIG. 7 is a block diagram illustrating an exemplary repair address space 500 for a BISR/repair controller 506. In some examples BISR/repair controller 506 provides each BISR/repair controller 112₁, 112₂, and 132 of FIG. 1. The BISR/repair controller 506 accesses the BISR/repair controller address/data 501 for read/write access. The repair address space 500 includes repair data segments 502₀ to 502_{N} corresponding to repair addresses 504₀ to 504_{N}, respectively, where “N” is any suitable number of repair data segments. Each RAddress 504₀ to 504_{N} are contiguous positive integer indices associated with a corresponding repair data segment 502₀to 502_{N}. The smallest repair data segment size may be a single bit, but the repair data segment size may be greater than a single bit. The repair data segments 502₀ to 502_{N} may be contiguous.

FIG. 8 is a functional block diagram illustrating an exemplary repair address translation process 510 between a BISR/repair controller 506 and a cache core 196. In response to a read or write request from the BISR/repair controller 506, the BISR/repair controller addresses 504₀ to 504_{N} are input to a repair address to repair system (RS) input address translation/remap process at 515 to generate corresponding addresses (ADDRESS_T 0 to ADDRESS_T M) 516₀ to 516_{M} suitable for the cache core 196, where “M” is any suitable number of corresponding addresses. For a write request, the repair data segments 502₀ to 502_{N} are processed by a repair data repacker at 511 to generate corresponding OTP segments 512₀ to 512_{M} that get encoded by the repair system for storage in the cache core 196. For a read request, the OTP segments 512₀ to 512_{M} are read from the cache core 196, decoded by the repair system, processed by the repair data repacker 511 to generate the corresponding repair data segments 502₀ to 502_{N} that are returned to the BISR/repair controller 506.

A BISR/repair controller address (RADDRESS) may be address translated into a format that is compatible with the cache core 196. In some examples, for security purposes, RAddress may be nonlinearly (e.g., secure hash) mapped into an address format compatible with the cache core 196. Hence, each element in the ADDRESS_T set is a remapped version of an element in the RADDRESS set. Each repair data segment is repacked/rearranged into a format that is compatible with the cache core 196. The repacked data, as shown in FIG. 8, is the OTP_SEG. The data packing/repacking at 511 and the address mapping at 515 may be implemented by the BISR controller accessor block 182 of the repair system 106 of FIG. 2. Therefore, each OTP_SEG is associated with exactly one ADDRESS _T. These addresses and data can then be encoded and decoded by the cache core 196 as previously described.

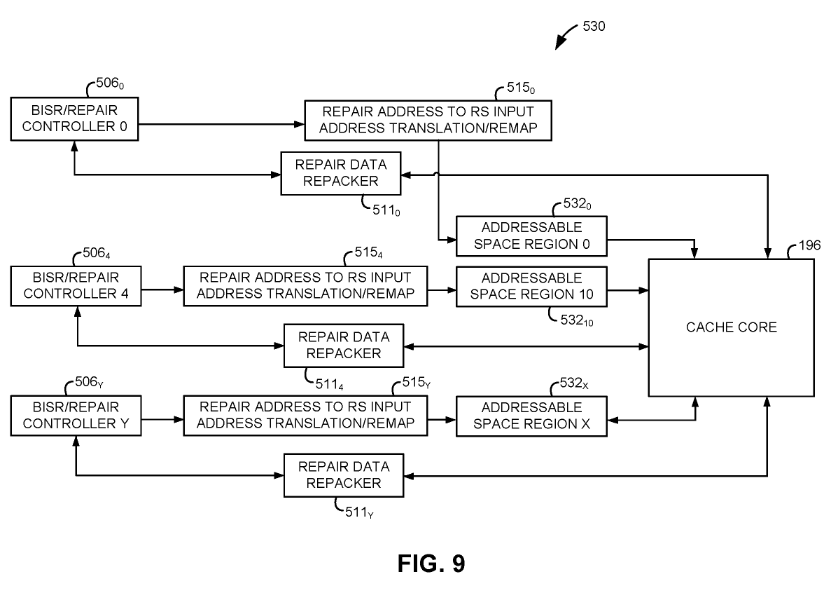

FIG. 9 is a functional block diagram illustrating an exemplary address and data translation process 530 between multiple repair controllers and a cache core of a repair system. For multiple repair controllers 506₀, 506₄, and 506_{Y}, in this example, the address space of each repair controller is mapped into address regions of the cache core 196. These address regions do not have to be contiguous. The address space for each repair controller space may map to multiple ADDRESS_T’s. In the example shown in FIG. 9, the BISR/repair controller 506₀ is mapped to addressable space region 0 as indicated at 532₀ via the repair address to repair system input address translation/remap process at 515₀ and the data is repacked by the repair data repacker 511₀. The BISR/repair controller 506₄ is mapped to addressable space region 10 as indicated at 532₁₀ via the repair address to repair system input address translation/remap process at 515₄ and the data is repacked by the repair data repacker 511₄. The BISR/repair controller 506_{Y} is mapped to addressable space region X as indicated at 532_{X} via the repair address to repair system input address translation/remap process at 515_{Y} and the data is repacked by repair data repacker 511_{Y}.

FIG. 10 is a functional block diagram illustrating an exemplary write process 600 including encoding repair data. For a write request from a BISR/repair controller (e.g., 112₁, 112₂, or 132 of FIG. 1; 506 of FIG. 7 or 8; or 506₀, 506₄, or 506_{Y} of FIG. 9), the cache core (e.g., 196 of FIG. 3) receives an ADDRESS_T as indicated at 602 and a corresponding OTP_SEG byte at indicted at 612. At 604, a first (home) hash is calculated based on the ADDRESS_T, and at 606 a second (probe) hash is calculated based on the ADDRESS_T. The first hash and the second hash may be calculated by the double hash generation block 226 of the cache core 196 of FIG. 3. At 608, the ADDRESS_L is found (in this example) based on the result of the home hash and the probe hash. The address may be found by the address finder FSM with table walker and linked hash block 230 of cache core 196 of FIG. 3. At 610, tag bits are generated, a tablewalker index may be generated, and a hashlink bit may be generated as previously described with reference to FIGS. 3 and 6. At 614, check bits are generated based on the OTP_SEG byte. The check bits may be generated by the check bit generation block 242 of the cache core 196 of FIG. 3. The check bits may include TMR check bits and/or CRC check bits as previously described with reference to FIG. 6. The encoded data including the tag bits, tablewalker index, hashlink bit, OTP segment, and check bits may then be stored in the cache at ADDRESS_L as indicated at 314_{L} (e.g., within SRAM 270 of cache core 196 of FIG. 3).

FIG. 11 is a functional block diagram illustrating an exemplary read process 650 including decoding repair data. For a read request from a BISR/repair controller (e.g., 112₁, 112₂, or 132 of FIG. 1; 506 of FIG. 7 or 8; or 506₀, 506₄, or 506_{Y} of FIG. 9), the cache core (e.g., 196 of FIG. 3) receives an ADDRESS_T as indicated at 602. At 604, a first (home) hash is calculated based on the ADDRESS_T, and at 606 a second (probe) hash is calculated based on the ADDRESS_T. The first hash and the second hash may be calculated by the double hash generation block 226 of the cache core 196 of FIG. 3. At 608, the ADDRESS_L is found (in this example) based on the result of the home hash and the probe hash. The address may be found by the address finder FSM with table walker and linked hash block 230 of cache core 196 of FIG. 3. At 610, tag bits are generated, a tablewalker index may be generated, and a hashlink bit may be generated as previously described with reference to FIGS. 3 and 6. At 652, the process 650 includes making sure the found address is correct. Determining whether the found address is correct may be implemented by address finder FSM with table walker and linked hash block 230 of cache core 196 of FIG. 3. The found address may be determined to be correct by comparing the tag bits stored in the cache to the tag bits generated at 610. If the tag bits match, the current location has the right home address or if not the home address, the table walked index matches the second hash offset times the tablewalker (TW) index. If the address is correct, the data is read from the cache at ADDRESS_L as indicated at 314_{L}. At 654, check bits are generated from the read data. The check bits may be generated by parity check generation block 258 of cache core 196 of FIG. 3. At 656, an error detection and correction stage processes the read data and check bits from cache 314_{L} and the check bits from 654 to return the OTP segment byte at 612. The error detection and correction stage may be implemented by the error detection and correction block 262 of cache core 196 of FIG. 3.

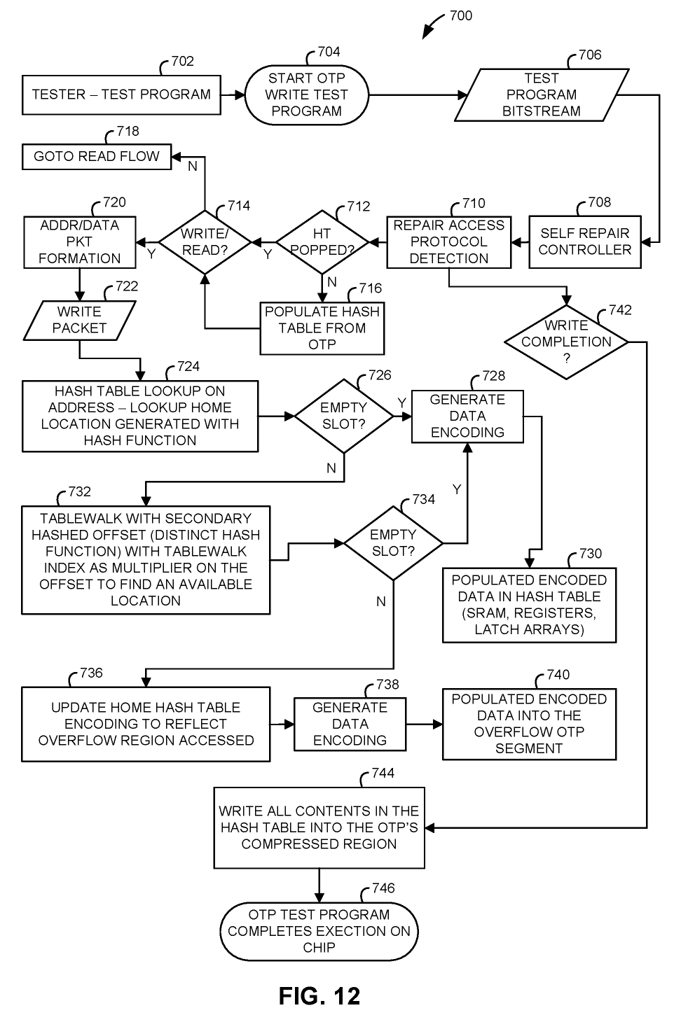

FIG. 12 is a flow diagram illustrating an exemplary method 700 for writing repair data to a repair system, such as repair system 106 of FIGS. 1 and 2. At 702, a tester runs a test program (e.g., instructs BISR controller 112₁ and BIST0 122₀ to test SRAM 118₁ and/or SRAM 118₂ and/or instructs BIST1 122₁ to test SRAM 118₃; instructs BISR controller 112₂ and BIST2 122₂ to test SRAM 118_{4,} SRAM 118₅, and/or SRAM 118₆; and/or instructs repair controller 132 and analog test controller 142 to test analog block 138₁ and/or analog block 138₂ of FIG. 1). At 704, method 700 starts an OTP write test program (e.g., via a BISR/repair controller) to generate a test program bitstream at 706 (e.g., including repair data). At 708, the test program bitstream is transmitted by the BISR/repair controller to the repair system (e.g., 106). At 710, method 700 detects the repair access protocol (e.g., via BISR protocol engine 174 of repair system 106 of FIG. 2). At 742, in response to the writing to the hash table being complete (e.g., no pending write requests from a BISR/repair controller), at 744 method 700 writes all contents in the hash table (e.g., stored in SRAM 270 of cache core 196 of FIG. 3) into the OTP’s (e.g., non-volatile memory 102 of FIG. 1) compressed region and the OTP test program completes execution on chip at 746.

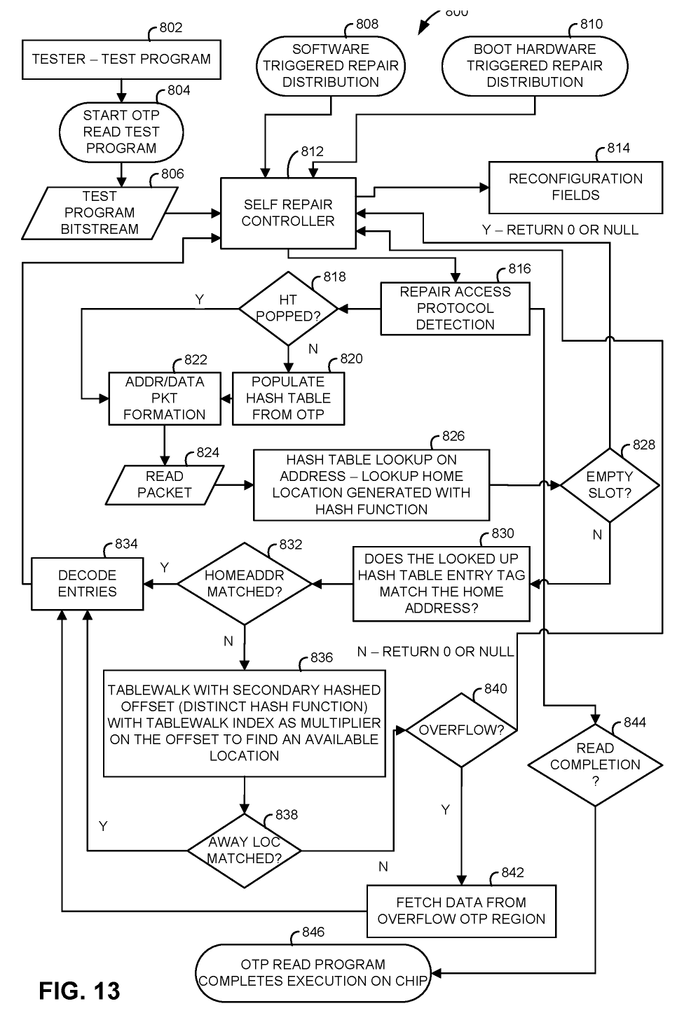

At 712, method 700 checks whether the hash table is populated (e.g., via repair system control FSM 178 of repair system 106 of FIG. 2). In response to the hash table not being populated, at 716 the hash table is populated from the OTP (e.g., via OTP master driver 168 and OTP image writing and loading sequencer 192 of repair system 106 of FIG. 2). With the hash table populated, at 714 method 700 determines whether the request is a read or write request (e.g., via BISR protocol engine 174 of repair system 106 of FIG. 2). In response to a read request, at 718 method 700 implements method 800 of FIG. 13 described below for a read request flow. In response to a write request, at 720 method 700 forms as address and data packet to generate a write packet at 722 (e.g., via BISR controller accessor block 182 of repair system 106 of FIG. 2 to translate the repair address and repack the data as previously described and illustrated with reference to FIG. 8). At 724, method 700 includes a hash table lookup on the address, i.e., lookup home location generated by the first (home) hash function (e.g., via the double hash generation block 226 and the address finder FSM with table walker and linked hash block 230 of cache core 196 of FIG. 3). At 726, method 700 checks (e.g., via the address finder FSM with table walker and linked hash block 230 of cache core 196 of FIG. 3) if the home location based on the first hash function is an empty slot in the hash table (e.g., within SRAM 270 of cache core 196 of FIG. 3). In response to the home location being an empty slot, at 728 method 700 generates encoded data (e.g., via code word generation block 246 and write data generation block 252 of cache core 196 of FIG. 3 and as described with reference to FIG. 6). At 730, method 700 writes the populated encoded data in the hash table (e.g., in SRAM 270 of cache core 196 of FIG. 3 or in registers, latch arrays, or other suitable type of memory).

In response to the home location being an occupied slot, at 732 method 700 tablewalks (e.g., via the address finder FSM with table walker and linked hash block 230 of cache core 196 of FIG. 3) the hash table with a secondary hashed offset (distinct hash function) (e.g., second (probe) hash is used to generate the secondary hashed offset) with a tablewalk index as a multiplier on the offset to find an available location. At 734, method 700 checks whether an empty slot was found based on the table walking. In response to the table walking finding an empty slot, at 728 method 700 generates encoded data and at 730 writes the populated encoded data in the hash table. In response to not finding an empty slot based on the table walking, at 736 method 700 updates the home hash table encoding to reflect the overflow region is accessed. At 738, method 700 generates encoded data and at 740 writes the populated encoded data in the overflow OTP segment (e.g., in overflow segment 304 of FIG. 4).

FIG. 13 is a flow diagram illustrating an exemplary method 800 for reading repair data from a repair system, such as repair system 106 of FIGS. 1 and 2. At 802, a tester runs a test program (e.g., BISR controller 112₁ instructs BIST0 122₀ to reconfigure SRAM 118₁ and/or SRAM 118₂ and/or instructs BIST1 122₁ to reconfigure SRAM 118₃; BISR controller 112₂ instructs BIST2 122₂ to reconfigure SRAM 118_{4,} SRAM 118₅, and/or SRAM 118₆; and/or repair controller 132 instructs analog test controller 142 to reconfigure analog block 138₁ and/or analog block 138₂ of FIG. 1). At 804, method 800 starts an OTP read test program to generate a test program bitstream at 806 to read the repair data to reconfigure/repair the tiles. Alternatively, or in addition, at 808 method 800 may include a software triggered repair that may initiate a read request and/or at 810, method 800 may include a boot hardware triggered repair that may initiate a read request.

At 812, in response to the test program bitstream, software trigger, or hardware trigger, the repair controller transmits a read request to the repair system (e.g., 106 of FIGS. 1 and 2). At 816, method 800 detects the repair access protocol (e.g., via BISR protocol engine 174 of repair system 106 of FIG. 2). At 844, in response to reading from the hash table being complete (e.g., no pending read requests from a BISR/repair controller), at 846 the OTP read program completes execution on chip.

At 818, method 800 checks whether the hash table is populated (e.g., the content of the non-volatile memory 102 of FIG. 1 has been loaded into the SRAM 270 of FIG. 3). If the hash table is not populated, at 820 method 800 populates the hash table from the OTP (e.g., via OTP master driver 168 and OTP image writing and loading sequencer 192 of repair system 106 of FIG. 2). With the hash table populated, at 822 method 800 forms an address and data packet to generate a read packet at 824 (e.g., via BISR controller accessor block 182 of repair system 106 of FIG. 2 to translate the repair address as previously described and illustrated with reference to FIG. 8). At 826, method 800 includes a hash table lookup on the address, i.e., lookup home location generated by the first (home) hash function (e.g., via the double hash generation block 226 and the address finder FSM with table walker and linked hash block 230 of cache core 196 of FIG. 3). At 828, method 800 checks whether the home location based on the first hash function is an empty slot in the hash table (e.g., within SRAM 270 of cache core 196 of FIG. 3). In response to the home location being an empty slot, method 800 returns a zero or null to the self repair controller at 812 indicating the read request failed.

In response to the home location being occupied, at 830 method 800 checks whether the looked up hash table entry tag matches the home address (e.g., tag bits match). At 832, if the home address is matched, then at 834 the entries are decoded and returned to the self repair controller at 812. At 832, if the home address does not match, then at 836 method 800 includes tablewalking with a secondary hashed offset (distinct hash function) with a tablewalk index as a multiplier on the offset to find an available location. At 838, in response to the away location (e.g., tablewalked location) matching (e.g., tag bits match), then at 834 the entries are decoded and returned to the self repair controller at 812. At 838, in response to the away location not matching, at 840 method 800 checks the overflow segment (e.g., overflow segment 304 of FIG. 4) for the data. In response to the data not being stored in the overflow segment, method 800 returns a zero or null to the self repair controller at 812 indicating the read request failed. In response to the data being stored in the overflow segment, at 842 method 800 fetches the data from the overflow OTP region, decodes the entries at 834, and returns the decoded data to the self repair controller at 812. At 814, method 800 includes reconfiguration of the fields using the read repair data (e.g., via the corresponding reconfiguration blocks 116₁ to 116₆ or 138₁ to 138₂ of FIG. 1).

It is to be understood that the features of the various exemplary embodiments described herein may be combined with each other, unless specifically noted otherwise.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

What is claimed is:

1. A system on a chip comprising:
a plurality of tiles, each tile comprising a repair controller;
a non-volatile memory; and
a repair system communicatively coupled between the non-volatile memory and the repair controller of each respective tile of the plurality of tiles,
wherein the repair system comprises:
a cache; and
control logic configured to:
receive a repair data write request and a respective repair address and corresponding repair data for a respective tile of the plurality of tiles from a respective repair controller and store the corresponding repair data in the cache in a redundancy encoded and compressed format;
write the contents of the cache to the non-volatile memory; and
receive a repair data read request and the respective repair address for the respective tile from the respective repair controller, read the corresponding redundancy encoded and compressed repair data from the cache, decompress the repair data, decode the corresponding repair data with error detection and correction logic, and output the corresponding repair data to the respective repair controller.

2. The system on a chip of claim 1, wherein the control logic is configured to populate the cache from the non-volatile memory in response to receiving the repair data read request and the cache not being populated.

3. The system on a chip of claim 1, wherein the control logic is configured to:
generate check bits for the corresponding repair data using an error-detecting code; and
store the check bits in the cache with the corresponding repair data.

4. The system on a chip of claim 3, wherein the check bits comprises triple modular redundancy check bits and/or cyclic redundancy check bits.

5. The system on a chip of claim 1, wherein the control logic is configured to:
calculate a first hash of the respective repair address using a first hash function;
calculate a second hash of the respective repair address using a second hash function different from the first hash function; and
select a cache address at which to store and/or read the corresponding repair data based on the first hash and/or the second hash.

6. The system on a chip of claim 5, wherein in response to the repair data write request, the control logic is configured to:
generate tag bits based on the respective repair address; and
store the tag bits in the cache with the corresponding repair data.

7. The system on a chip of claim 6, wherein in response to the repair data read request, the control logic is configured to:
generate verification tag bits based on the respective repair address;
read the corresponding repair data and tag bits from the cache based on the selected cache address;
verify the generated verification tag bits match the tag bits read from the cache with the corresponding repair data;
perform error detection and correction on the corresponding repair data; and
output the corresponding repair data to the respective repair controller.

8. The system on a chip of claim 5, wherein in response to the repair data write request, the control logic is configured to:
generate a tablewalker index based on the selected cache address in response to the selected cache address being in a hash table segment of the cache; and
store the tablewalker index in the cache with the corresponding repair data.

9. The system on a chip of claim 5, wherein in response to the repair data write request, the control logic is configured to:
generate a hashlink based on the selected cache address in response to the selected cache address being in an overflow segment of the cache; and
store the hashlink in the cache with the corresponding repair data.

10. The system on a chip of claim 1, wherein the non-volatile memory comprises a hash table segment and an overflow segment.

11. The system on a chip of claim 1, wherein the cache comprises a static random access memory (SRAM), a plurality of registers, or a plurality of latch arrays.

12. The system on a chip of claim 1, wherein the non-volatile memory comprises a one-time programmable memory.

13. A system on a chip comprising:
a plurality of tiles, each tile comprising a repair controller;
a non-volatile memory; and
a repair system communicatively coupled between the non-volatile memory and the repair controller of each respective tile of the plurality of tiles,
wherein the repair system comprises:
a cache to store corresponding repair data for the plurality of tiles; and
repair system control logic configured to:
write the contents of the cache to the non-volatile memory;
load the contents of the non-volatile memory to the cache;
access the cache for a repair data write operation in response to a repair data write request from a respective repair controller; and
access the cache for a repair data read operation in response to a repair data read request from a respective repair controller.

14. The system on a chip of claim 13, wherein the repair system control logic comprises:
a repair controller arbiter to serialize repair data write requests and repair data read requests received from each repair controller;
a protocol engine to process the serialized repair data write requests and repair data read requests; and
a finite state machine to control the operations of the repair system.

15. The system on a chip of claim 13, wherein the cache comprises:
a static random access memory (SRAM); and
cache control logic configured to:
generate a first hash and a second hash based on a respective repair address for corresponding repair data for the plurality of tiles;
select an address of the SRAM based on the first hash and/or the second hash at which to store the corresponding repair data;
generate check bits for the corresponding repair data;
combine the corresponding repair data with the check bits; and
write the corresponding repair data to the selected address in the SRAM.

16. The system on a chip of claim 15, wherein the cache control logic is configured to:
enable the SRAM to read the corresponding repair data from the selected address in the SRAM;
detect errors and/or correct the corresponding repair data; and
pass the corresponding repair data to the repair system control logic.

17. A method for self-repair of tiles of a system on a chip, the method comprising:
executing a built-in self-test of each tile of a plurality of tiles of the system on a chip to generate corresponding repair data for each tile;
receiving, at a repair system from each tile, a respective repair address and corresponding repair data;
selecting a cache address based on the respective repair address at which to write the corresponding repair data to a cache; and
writing the contents of the cache to a non-volatile memory.

18. The method of claim 17, wherein selecting the cache address comprises:
hashing the respective repair data address to generate a respective hash table write address;
implementing a hash table lookup on the respective hash table write address in a hash table segment of the cache;
in response to the hash table lookup on the respective hash table write address finding an empty slot in the hash table segment, writing the corresponding repair data to the empty slot;
in response to the hash table lookup on the respective hash table write address finding an occupied slot in the hash table segment:
hashing the respective repair data address to generate a corresponding hash table write offset;
table walking the hash table segment based on the hash table write offset to find an empty slot in the hash table segment;
in response to the table walking finding an empty slot in the hash table segment, writing the corresponding repair data to the empty slot; and
in response to the table walking not finding an empty slot in the hash table segment, writing the corresponding repair data to an overflow segment of the cache or in the non-volatile memory.

19. The method of claim 18, further comprising:
triggering a read of corresponding repair data to repair a respective tile;
in response to the cache not being populated, populating the cache from the non-volatile memory;
hashing the respective repair data address to generate a respective hash table read address;
implementing a hash table lookup on the respective hash table read address in the hash table segment of the cache;
in response to the hash table lookup on the respective hash table read address finding an empty slot in the hash table segment, returning a null to the respective tile;
in response to the hash table lookup on the respective hash table read address finding an occupied slot in the hash table segment:
verifying the stored data at the hash table address corresponds to the respective repair address;
in response to the verification of the stored data at the hash table address corresponds to the respective repair address, returning the corresponding repair data stored at the hash table read address;
in response to not verifying the stored data at the hash table read address corresponds to the respective repair address:
hashing the respective repair data address to generate a corresponding hash table read offset;
table walking the hash table segment based on the hash table read offset to find a next slot in the hash table segment;
in response to the table walking finding the next slot empty, returning a null to the respective tile;
in response to the table walking finding the next slot occupied, verifying the stored data at the occupied slot corresponds to the respective repair address.

20. The method of claim 19, further comprising:
in response to the table walking exhausting the entire hash table segment with no occupied slot corresponding to the respective repair address, reading the corresponding repair data from the overflow segment of the cache.
